(19) United States
(12) Patent Application Publication
(10) Pub. No.: US 2008/0033671 A1
(43) Pub. Date: Feb. 7, 2008

(54) Method And Device For Measuring Physical Variables Using Piezoelectric Sensors And A Digital Integrator

(76) Inventors: Christopherus Bader, Neftenbach (CH); Robert Hoffmann, Buchs (CH)

Correspondence Address: BACHMAN & LAPOINTE, P.C., 900 CHAPEL STREET, SUITE 1201, NEW HAVEN, CT, 06510, US

(21) Appl. No.: 11/661,440

(22) PCT Filed: Aug. 12, 2005
(86) PCT No.: PCT/EP05/08816

§ 371 Date: Feb. 28, 2007

(30) Foreign Application Priority Data
Sep. 1, 2004 (DE) 10 2004 042 668.6
Feb. 14, 2005 (DE) 10 2005 006 806.5

(51) Int. Cl. G01R 19/00

(52) U.S. Cl. 702/64

(57) ABSTRACT

A method for measuring physical variables using piezoelectric sensors, which generate an input voltage (Iₑ) for an amplifier is provided. The voltage is fed from the amplifier to a digital integrator.

The invention relates to a method for measuring physical variables using piezoelectric sensors that generate an input voltage for an amplifier.

### PRIOR ART

Physical variables such as, for example, pressures, forces, accelerations, expansions etc are widely acquired by means of piezoelectric measuring techniques. Piezoelectric measuring techniques are based on the piezoelectric effect, electric charges being generated on the surface of piezocrystals when the latter are deformed. This electric charge is fed to a current/voltage transformer in which there is located an amplifier to which a capacitor is assigned in the bypass. Such an arrangement is described, for example, in CH 494 967.

It goes without saying that the piezoelectric sensor generates very small charges that are transported with lightning speed onto the capacitor in the integrator. The larger the resistance in the cable, the lower is the required compensating current for compensating possible offset input voltages of the integrator. This leads to drifting of the signal. As cable resistance becomes smaller, a portion of the charge generated is likewise lost before transport into the capacitor of the integrator.

Temperature also plays a role in this case. The warmer the surroundings, the worse the drift. If such sensors are therefore applied, for example to injection molding machines, the reduction in drift is exceptionally expensive.

In order to be able to transport such small charges, the cables must have a very high resistance, specifically in a range of 10¹²Ω to 10¹⁵Ω. If such cables are touched merely with the finger, resistance collapses, that is to say handling such cables is a very delicate matter and extremely expensive.

EP 0 253 016 exhibits a charge amplifier circuit in which there are provided a first operational amplifier, an integration capacitor between the inverting input and the output of the first amplifier, and a second amplifier whose input is connected to the output of the charge amplifier circuit, and whose output is connected via a resistor and, during the resetting face, a resetting device to the inverting input of the first amplifier. The aim in this case is to form the charge amplifier circuit as a measuring circuit by virtue of the fact that the integration capacitor can be short circuited by a resistor via the resetting device such that when the resetting device is active the integration capacitor automatically causes a charge to flow that compensates the zero point offset of the output voltage of the charge amplifier circuit during the zero phase following the resetting phase.

The charge/voltage transformation in this charge amplifier is therefore organized with the aid of a capacitor. Since the integration of the function:

$$Ua ( t ) = \frac{1}{C} * {\int }_{o}^{t} Ie ( t ) ⅆ t + Ua ( t = 0 )$$

is organized in the capacitor, the voltage currents of the capacitor, the line to the sensor and the input amplifier must be very low. If such a charge amplifier is used for measurements over lengthy periods, the measuring signal drifts since leakage resistances of less than 10¹⁵Ω can be realized only with difficulty, and the input amplifiers have an offset.

### OBJECT

The present invention is based on the object of developing a low-resistance and driftless measurement of physical variables using piezoelectric sensors.

### ACHIEVEMENT OF THE OBJECT

The achievement of the object results from feeding the voltage from the amplifier to a digital integrator.

A microcomputer can be provided in the integrator for the purpose of processing the voltage fed from the amplifier. However, the method can also be implemented with the aid of a so-called “freely programmable logic module”, such as a DSP, EPLD, CPLD or STGA (free programmable date array). These freely programmable logic modules could independently take over the task of a microcomputer, but it could also constitute a part of the microcomputer.

The digital integrator preferably forms a constant sum of the force differences present in neighboring time windows. In this case, the integrator calculates the integral over the current at time discrete points, the infinite sum being formed. The cycle of a process is determined in the integrator, and a quasi-static, piezoelectric amplifier is constructed without a cycle controller (operate reset circuit).

Since, owing to the current amplifier, the voltage at the sensor is respectively kept at 0 volts, and no voltage is stored at the capacitors, this method is particularly suitable for connecting piezosensors of very low resistance to the measuring amplifier, it being possible at the same time to eliminate the drift and, if the process is known, to work without resetting at the pressure intensifier. The current amplifier generates in each case by means of a resistor the same current as the current that is output by the sensor upon the action of force with a negative polarity. A current that behaves identically to the force that has changed in this period flows between two temporally offset points in time.

In one example of application, the resistor is arranged in a bypass around an amplifier. That is to say, in this case the resistor replaces the known capacitor or the known capacitance.

In a further exemplary embodiment, the resistor is integrated in the sensor. This yields the interesting possibility of using a single amplifier for all the sensors, there being no need to undertake any sort of gain corrections or gain changeovers. The principle consists in that a voltage is applied at the resistor by the charge while current is flowing.

Furthermore, it is provided in a preferred example of application to limit the current upstream of the current/voltage converter. This is performed by a resistor that is connected between the input and the amplifier. It can also be provided in addition that branching off to a frame takes place between the input and the limiting resistor, a capacitor being connected in the branch circuit. This capacitor prevents strong current rises, and thus permits low scanning rates for the downstream A/D converter.

The resistors in the current/voltage converter can be varied in order to take account of different sensitivities of sensors.

Given the arrangement of the resistor in the sensor, it is possible to generate for all sensor types uniform output signals that can be amplified by a charge amplifier having only a single gain, the current/voltage converter then being replaced by a voltage amplifier. It is important that it is likewise possible thus for manufacturing tolerances of the piezocrystals to be corrected electronically, and their sensitivity is automatically detected (“PRIASED function”).

In order to reduce the input resistance of the piezoelectric amplifier, all the charge carriers are preferably to be discharged at once to frame. In this case, there is no voltage present at the sensor that can be reduced by losses in the cable. The digital integrator undertakes the requisite integration in order to prevent drift phenomena.

### DESCRIPTION OF THE FIGURES

Further advantages, features and details of the invention emerge from the following description of preferred exemplary embodiments, and with the aid of the drawing, in which:

FIG. 1 shows a block diagram of an inventive method for measuring physical variables in conjunction with low resistance and without drift, using piezoelectric sensors;

FIG. 2 shows a block diagram of a field of use of the inventive method according to FIG. 1; and

FIG. 3 shows a block diagram of a further field of use of the inventive method.

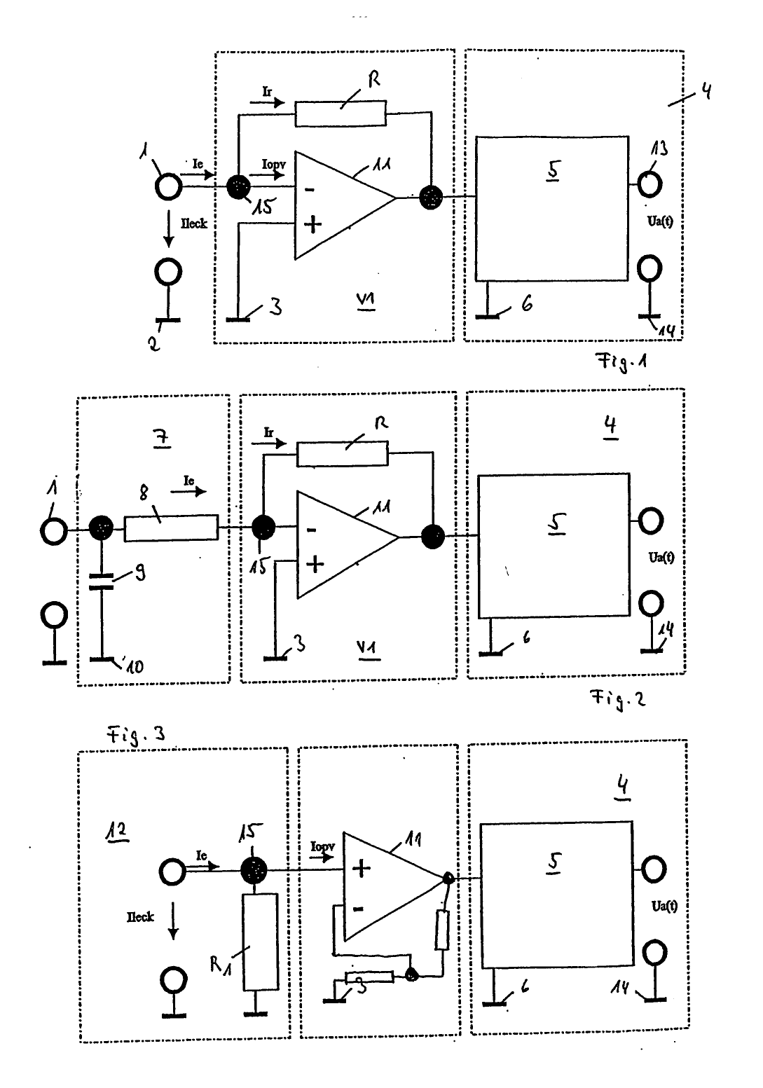

In accordance with FIG. 1, an input current Iₑ passes via an input 1 from a piezoelectronic sensor (not illustrated in more detail) to a current/voltage converter V1. A leakage current I_{leck} flows off to frame 2.

The current/voltage converter V1 includes a current amplifier 11 that operates to frame 3. Furthermore, connected to it is a digital integrator 4 that is essentially formed from a microcomputer 5 that is, in turn, connected to frame 6. The microcomputer has an output 13 for the calculated voltage Ua(t), which is connected in turn to frame 14.

The mode of operation of the present invention is as follows:

Upon application of the pressure, the piezoelectric sensor (not shown in more detail), which can serve, for example, as a pressure sensor, generates a current which it conducts to input 1 as input current Iₑ.

It holds for the system that: Iₑ=Iᵣ+Iₒₚᵥ+I_{leck}

The input current Iₑ is then divided at a nodal point 15 into the current Iᵣ to the resistor R, and the current Iₒₚᵥ to an inverted input of the current amplifier 11 and I_{leck}. The leakage current I_{leck} is discharged via the frame 2.

Furthermore, it must be that I_{R}>1000 Iₒₚᵥ and it must hold for small measuring errors that:
Iₐ>1000 (Iₒₚᵥ+I_{leck})

The current amplifier 11 respectively generates through the resistor R the same current as the current Iₑ that is output by the sensor when force is acting. A current that behaves in an identical fashion to the force changed in this period flows between two temporally offset instants.

The digital integrator 4 is connected to the output of the current amplifier 11, and operates according to the following formula:

$$Ua ( t ) = R * {\int }_{o}^{t} {I}_{θ} ( t ) ⅆ t \qquad Equation 1$$

The digital integrator 4 replaces the previously known capacitor (analog integrator), at which the charge is able to be reduced. No values are lost in the microcomputer system.

This digital integrator 4 forms the infinite sum of the difference signals that are measured at the sensor between two access points in each case. That is to say, the computing operation in a microcomputer is performed according to the following formula:

$$dUa ( t = t 2 - t 1 ) = R * \frac{{\int }_{t 1}^{t 2} Ie ( t ) ⅆ t}{t 2 - t 1} \qquad Equation 2$$

It is not critical here whether the force is produced by pressure via a surface, is a directly acting force. The following general equation results:

$$Ua ( t = t 0 - t ( ende ) = R * {\sum }_{t 0}^{t ( ende )} \frac{{\int }_{t ( s - 1 )}^{t 0} Ie ( t ) ⅆ t}{t ( n - 1 ) - t ( tn )} \qquad Equation 3$$

Thus, only the differential is amplified, and so a leakage current through a leakage resistance can no longer exert an influence later by digital offset measurement. As mentioned above, it need only hold that the current through the leakage resistance is 100 times smaller than the current I_{R} through the resistor R, so that the measuring error is <1%. It follows that a leakage resistance of 10⁷Ω (that is to say 6 powers of ten lower) suffices for offset voltages of 5 mV, and so the cable and sensor can be designed in a much more favorable way.

The value stored in the computer cannot drift, and so by contrast with the prior art possible offset properties of the current/voltage converter V1 can be eliminated by designing the program. All that need be done is to eliminate the offset starting value in the analog part in a digital fashion.

Since the current/voltage converter keeps the voltage at the sensor at 0 volts in each case, and no voltage is stored at the capacitors, this method is particularly suitable for connecting piezosensors of very low resistance to the measuring amplifier, it being possible (independently of a change in force/pressure) to eliminate the drift simultaneously and, to the knowledge of the process, to operate on the pressure intensifier without resetting.

### EXAMPLE

In the case of an example of a sensor with 10 pC/bar and a full scale deflection of 4000 bar that reaches full scale deflection within 1 ms by a linear rise in pressure, the following current would flow in the course of 1 ms:

$$I = \frac{ⅆ Q}{ⅆ t} = \frac{10 ( pc / bar ) * 4000 bar}{1 ms} = 40 μ A \qquad Equation 4$$

If the measuring error is to be <0.1% for this example, and assuming an amplifier with an offset of approximately 5 mV for the current amplifier V1, it is possible to calculate the leakage resistance, which may be connected in parallel with the cable.

$$\frac{Ie}{Ileak} = \frac{1000}{1} \qquad Equation 5$$

for the measuring error of 0.1%

The resistance connected in parallel with the sensor in this case would be:

$$R = \frac{Uoffset}{I leak} = \frac{5 mV}{400 nA} = 12500 Ω \qquad Equation 6$$

This means that the leakage resistance of the cable may be at 12.5 KΩ given a 5 mV offset at the input of the new pressure intensifying method.

By comparison therewith, according to EP 253 016 A1 the input resistance of the circuit must be at least 10¹⁵Ω.

When the entire measuring range is swept within 1 s, it follows from equation 4 that:

$$I = \frac{ⅆ Q}{ⅆ t} = \frac{10 ( pc / bar ) * 4000 bar}{1 s} = 40 nA \qquad Equation 7$$

It follows from equations 5 and 6 that in this case the leakage resistance connected in parallel to the line may still be:

$$R = \frac{Uoffset}{I leck} = \frac{5 mV}{400 pA} = 12.5 M Ω \qquad Equation 8$$

In this example, the input resistance can be smaller by a factor of 80*10^{[illegible]} to 80*10⁶ for example measuring method.

It follows that the novel amplifier should be very easily capable of implementing input resistances of 100 MΩ without the possibility of the occurrence of measuring errors or drift phenomena. This is smaller by a factor of 10 000 than in the case of the integrator known from EP 253 016 A1.

It is also possible that the computer analyzes the process and can itself take the decision as to when the amplifier is to be reset. This is attended by the advantage that the signal to be considered is not to be synchronized with a digital signal of the machine, or a short pulse (edge in the case of operate or reset) suffices.

In the field of use in accordance with FIG. 2, a current-limited method is shown in conjunction with the use of a conventional sensor, but with a line of low resistance. In this case, a current limiter 7 is connected between the input 1 and the current/voltage converter V1. Said current limiter consists of a limiting resistor 8 between which and the input 1 there is located, with the interposition of a capacitor 9, a branch circuit to a frame 10. The capacitor 9 and the resistor 8 jointly prevent strong current rises, and thereby permit low scanning rates.

In this exemplary embodiment, a compromise possible for the maximum rates of rise that are technically possible in the measurement systems is adopted to the effect that the scanning rates of the integrator 4 can be reduced while the integration error is nevertheless small. In this case, however, the different sensitivities of the sensors still have to be set at the amplifier 11. The limiting resistance 8 prevents the charge from flowing off at lightning speed into the current/voltage transformer V1, and so the dynamics of the current/voltage transformer V1 can be somewhat restricted.

In the further field of use in accordance with FIG. 3, a resistor R₁ via which the charge is quickly discharged is situated in a sensor denoted in general by 12. A changeover of measuring range (correction of sensitivity) is performed in the sensor 12 itself. Since there are no further measuring ranges in the amplifier 11, the interesting possibility arises of using only a single amplifier 11 for all the sensors, there being no need to undertake any sort of gain corrections or changeovers in gain. No current amplifier is formed until the interconnection of R₁ and the amplifier 11. The principle consists in that owing to the charge a voltage is present at the resistor when current is flowing. The digital integrator 4 adds only the voltages present at the discrete instants.

The result of this is a setting of the measuring range of the measuring chain in the sensor and a compensation of the sensor differences (automatic detection of sensor and sensitivity), as well as a measuring range compensation. The correction factor of the crystal is compensated (percentage error), and the measuring range of the crystal can be measured from outside.

If a start is made from equation 4, and if the aim in this case is not to overshoot a 1 volt voltage, the resistance would be only 25 KΩ. This means that, given a 0.1% measuring error, a 25 MΩ resistance may be connected in parallel with the line, and this constitutes a value that is inconceivable for the present piezoelectric amplifiers. No amplifier produced using the prior art could still undertake measurements given a cable resistance of 20 MΩ.
Dr. Peter Weiss & Dipl.-ing. A. Brecht
Patentanwälte
European Patent Attorney

File reference: P3208/PCT Date: Dec. 8, 2005 W/HU

List of reference symbols

| | |
|---|---|
| 1 | Input |
| 2 | Frame |
| 3 | Frame |
| 4 | Digital |
| | integrator |
| 5 | Microcomputer |
| 6 | Frame |
| 7 | Current limiter |
| 8 | Limiting resistor |
| 9 | Capacitor |
| 10 | Frame |
| 11 | Amplifier |
| 12 | Sensor |
| 13 | Output |
| 14 | Frame |
| 15 | Nodal point |
| 16 | |
| 17 | |
| 18 | |
| 19 | |
| 20 | |
| 21 | |
| 22 | |
| 23 | |
| 24 | |
| 25 | |
| 26 | |
| 27 | |
| 28 | |
| 29 | |
| 30 | |
| 31 | |
| 32 | |
| 33 | |
| 34 | |
| 35 | |
| 36 | |
| 37 | |
| 38 | |
| 39 | |
| 40 | |
| 41 | |
| 42 | |
| 43 | |
| 44 | |
| 45 | |
| 46 | |
| 47 | |
| 48 | |
| 49 | |
| 50 | |
| 51 | |
| 52 | |
| 53 | |
| 54 | |
| 55 | |
| 56 | |
| 57 | |
| 58 | |
| 59 | |
| 60 | |
| 61 | |
| 62 | |
| 63 | |
| 64 | |
| 65 | |
| 66 | |
| 67 | |
| 68 | |
| 69 | |
| 70 | |
| 71 | |
| 72 | |
| 73 | |
| 74 | |
| 75 | |
| 76 | |
| 77 | |
| 78 | |
| 79 | |
| Iₑ | Input current |
| I_{R} | Current at R |
| Iₚₚᵥ | Current at V1 |
| R₁R | Resistor |
| V1 | current/voltage |
| | transformer |

1-19. (canceled)

20. A method for measuring physical variables during operational processes using piezoelectric sensors that generate an input current (Ie) for an amplifier that is located in a current/voltage transformer comprising inputting a voltage by the amplifier directly to a digital integrator.

21. The method as claimed in claim 20, comprising dividing the input current (Iₑ) in the current/voltage transformer operating to a frame into a current (Iₒₚᵥ) to the amplifier and a current (I_{R}) to a resistor (R), so that the current/voltage transformer is formed thereby.

22. The method as claimed in claim 21, comprising using a microcomputer in the integrator to calculate a voltage (Uₐ(t)) according to the following formula:
$$Ua ( t ) = {R}^{*} {\int }_{o}^{t} {I}_{e} ( t ) ⅆ t$$
wherein
Uₐ is an output voltage at the microcomputer,
R is the value of the resistor, and
Iₑ is the input current for the current/voltage transformer.

23. The method as claimed in claim 20, comprising arranging a resistor upstream of the amplifier in the sensor itself.

24. The method as claimed in claim 20, comprising forming a constant sum of force differences present in neighboring time windows in the integrator downstream of the amplifier.

25. The method as claimed in claim 24, comprising calculating an integral over current at time discrete points with the integrator, so an infinite sum is formed.

26. The method as claimed in claim 25, comprising determining a cycle of operational processes in the integrator, and constructing a quasi-static, piezoelectric amplifier without a cycle controller.

27. The method as claimed in claim 26, further comprising limiting the current upstream of the amplifier.

28. The method as claimed in claim 21, comprising feeding the current (Iₒₚᵥ+I_{lock}) to the amplifier at least 100 times smaller than a smallest input current (Iₑ) coming from the sensor.

29. A device for measuring physical variables using piezoelectric sensors that generate an input current (Iₑ) for an amplifier downstream of which a digital integrator is connected, comprising the amplifier being part of a current/voltage transformer, and the current/voltage transformer being connected upstream of the digital integrator.

30. The device as claimed in claim 29, further comprising a microcomputer being integrated in the digital integrator.

31. The device as claimed in claim 29, further comprising a digital indicator including a freely programmable logic module.

32. The device as claimed in claim 29, further comprising a bypass with an integrated resistor is assigned to the amplifier.

33. The device as claimed in claim 32, wherein different sensitivities of sensors can be set by different resistors having different resistance values.

34. The device as claimed in claim 29, further comprising a resistor connected between an input and the amplifier.

35. The device as claimed in claim 34, wherein branching off between the input and the resistor is a line to a frame in which a capacitor is connected.

36. The device as claimed in claim 29, further comprising a resistor discharged to a frame branches off between an input and the amplifier.

37. The device as claimed in claim 29, further comprising a plurality of charge carriers and all of the charge carriers being connected to a frame.
